(19) United States
(12) Patent Application Publication
(10) Pub. No.: US 2011/0256682 A1
(43) Pub. Date: Oct. 20, 2011

(54) Multiple Deposition, Multiple Treatment Dielectric Layer For A Semiconductor Device

(75) Inventors: Xiong-Fei Yu, Hsinchu (TW); Wei-Yang Lee, Taipei City (TW); Da-Yuan Lee, Jhubei City (TW); Kuang-Yuan Hsu, Fongyuan City (TW); Yuan-Hung Chiu, Taipei (TW); Hun-Jan Tao, HsinChu (TW); Hongyu Yu, Singapore (SG); Wu Ling, Singapore (SG)

(73) Assignee: TAIWAN SEMICONDUCTOR MANUFACTURING COMPANY, LTD., Hsin-Chu (TW)

(21) Appl. No.: 12/761,159

(22) Filed: Apr. 15, 2010

(51) Int. Cl. H01L 21/336; H01L 21/28

(52) U.S. Cl. 438/287; 438/591; 257/E21.409; 257/E21.192

(57) ABSTRACT

A method is provided for fabricating a semiconductor device. A semiconductor substrate is provided. A first high-k dielectric layer is formed on the semiconductor substrate. A first treatment is performed on the high-k dielectric layer. In an embodiment, the treatment includes a UV radiation in the presence of O₂ and/or O₃. A second high-k dielectric layer is formed on the treated first high-k dielectric layer. A second treatment is performed on the second high-k dielectric layer. In an embodiment, the high-k dielectric layer forms a gate dielectric layer of a field effect transistor.

### BACKGROUND

The present disclosure relates generally a semiconductor device and, more particularly, to a method of forming dielectric layer of a semiconductor device (e.g., a gate dielectric layer of a field effect transistor).

As technology nodes shrink, in some IC designs, there has been a desire to replace the typically polysilicon gate electrode with a metal gate electrode to improve device performance with the decreased feature sizes. One process of forming a metal gate stack is termed “gate last” process in which the final gate stack is fabricated “last” which allows for a reduced number of subsequent processes, including high temperature processing, that must be performed after formation of the gate. As the dimensions of transistors decrease, the thickness of the gate oxide typically must also be reduced to maintain performance. In order to reduce gate leakage, high dielectric constant (high-k) gate dielectric layers are typically used to allow greater physical thicknesses while maintaining the same effective thickness as would be provided by a typical gate oxide used in larger technology nodes. Other benefits of a gate last, high k dielectric scheme include suppression of growth of an interfacial layer underlying the gate dielectric which allows for a beneficial equivalent oxide thickness (EOT), a reduction of gate leakage, and a proper work function of a metal gate.

There are challenges to implementing such features and processes in semiconductor fabrication however. As-deposited high-k dielectric layers may include pre-existing traps such as oxygen vacancies or impurities. These can affect the resultant semiconductor device performance. Typically an anneal is performed to improve the high-k dielectric layer performance. However, as this increases the thermal budget, it is disadvantageous. For example, it can cause increased EOT by interfacial layer re-growth.

### SUMMARY

In one embodiment, a method of fabricating a semiconductor device is provided. The method includes providing a semiconductor substrate and forming a first high-k dielectric layer on the semiconductor substrate. A first treatment is performed on the first high-k dielectric layer, thereby forming a first treated high-k dielectric layer. A second high-k dielectric layer is formed on the first treated high-k dielectric layer. Thereafter, a second treatment is performed on the second high-k dielectric layer.

In another embodiment, a method includes forming a first portion of a gate dielectric layer on a semiconductor substrate. A first treatment is performed on the first portion of the gate dielectric layer. Thereafter, a second portion of the gate dielectric layer is formed directly on the first treated first portion. A second treatment is then performed on the second portion of the gate dielectric layer.

In yet another embodiment, a method of semiconductor fabrication is provided that includes forming a dummy gate structure on a semiconductor substrate. A source and drain region are formed adjacent the dummy gate structure. Thereafter, the dummy gate structure is removed to form a trench. A first portion of a high-k dielectric layer is formed on the substrate including in the trench. The first portion of the high-k dielectric layer is treated. A second portion of the high-k dielectric layer is formed on the substrate overlying the treated first portion. The second portion of the high-k dielectric layer is treated. A metal gate is formed on the high-k dielectric layer.

### BRIEF DESCRIPTION OF THE DRAWINGS

FIG. 1 is a flow chart of an embodiment of a method of forming a dielectric layer on a substrate.

FIGS. 2, 3, 4, 5, and 6 are cross-sectional views of a semiconductor device corresponding to steps of the method of FIG. 1.

FIG. 7 is a flow chart of an embodiment of a “gate last” method including forming a dielectric layer according to the present disclosure.

FIGS. 8, 9, 10, 11, 12, and 13 are cross-sectional views of a semiconductor device corresponding to steps of the method of FIG. 7.

FIG. 14 is a flow chart of an embodiment of a “gate last” method including forming the gate dielectric “last” and forming a dielectric layer according to the present disclosure.

FIGS. 15, 16, 17, 18, and 19 are cross-sectional views of a semiconductor device corresponding to steps of the method of FIG. 14.

### DETAILED DESCRIPTION

The present disclosure relates generally to forming a semiconductor device on a substrate and, more particularly, to fabricating a dielectric layer (e.g., gate dielectric layer) of a semiconductor device. It is understood, however, that the following disclosure provides many different embodiments, or examples, for implementing different features of the invention. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed. In addition, the present disclosure provides examples of a “gate last” metal gate process, however one skilled in the art may recognize applicability to other processes (e.g., gate first) and/or use of other materials.

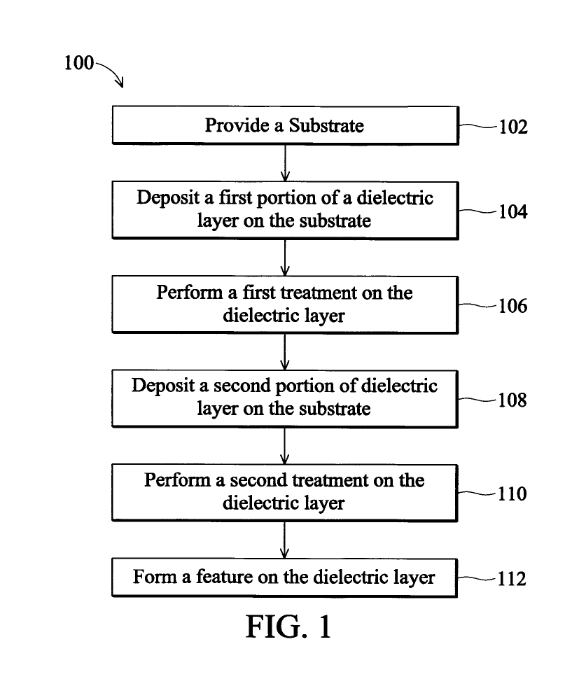

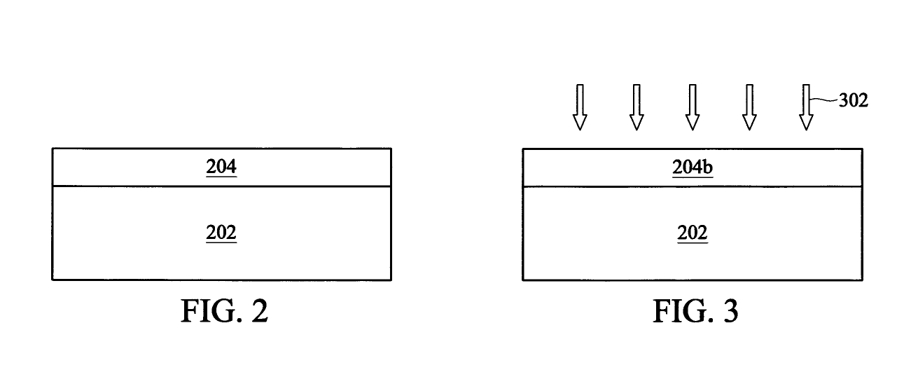

Referring to FIG. 1, illustrated is a flowchart of a method 100. The method 100 provides for forming features of a semiconductor device including a dielectric layer. The method 100 may be used to form a gate dielectric layer of a semiconductor device. FIGS. 2, 3, 4, 5, and 6 illustrate cross-sectional views of an embodiment of a semiconductor device at various stages of fabrication corresponding to the method 100 of FIG. 1.

The method 100 begins at block 102 where a substrate is provided. The substrate is typically a semiconductor substrate. Referring to the example of FIG. 2, a substrate 202 is illustrated. In an embodiment, the substrate 202 is a silicon substrate (e.g., wafer) in crystalline structure. The substrate 202 may include various doping configurations depending on design requirements (e.g., p-type substrate or n-type substrate). Other examples of the substrate 202 may also include other elementary semiconductors such as germanium and diamond. Alternatively, the substrate 202 may include a compound semiconductor such as, silicon carbide, gallium arsenide, indium arsenide, or indium phosphide. Further, the substrate 202 may optionally include an epitaxial layer (epi layer), may be strained for performance enhancement, and/or may include a silicon-on-insulator (SOI) structure. In an embodiment, the substrate 202 includes an interfacial layer formed thereon. The interfacial layer may include SiO₂, SiON, chemical oxide, and/or other suitable material. The interfacial layer may be formed by suitable deposition and/or oxidation processes.

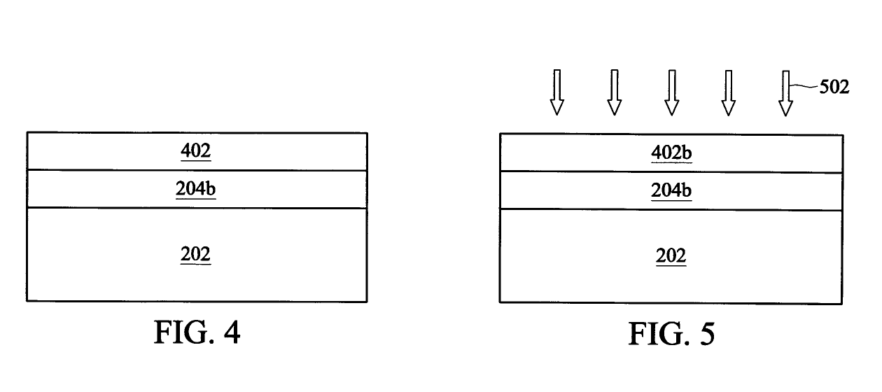

The method 100 then proceeds to block 104 where a first portion of a dielectric layer is formed on the substrate. The dielectric layer may form the gate dielectric of a gate structure of a semiconductor device (e.g., a dielectric layer between the gate and substrate of a field effect transistor (FET)). In an embodiment, the dielectric layer is a high dielectric constant (high-k or HK) material. The high-k material may include metal oxides, metal nitrides, metal silicates, transition metal-oxides, transition metal-nitrides, transition metal-silicates, oxynitrides of metals, metal aluminates, zirconium silicate, zirconium aluminate, combinations thereof, or other suitable compositions. Example high-k dielectrics include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable materials. Alternatively, the high-k dielectric layer may include other high-k dielectrics such as LaO, AlO, ZrO, TiO, Ta₂O₅, Y₂O₃, SrTiO₃ (STO), BaTiO₃ (BTO), BaZrO, HfLaO, HfSiO, LaSiO, AlSiO, (Ba,Sr)TiO₃ (BST), Al₂O₃, Si₃N₄, and/or other suitable materials. Referring to the example of FIG. 2, a high-k dielectric layer 204 is disposed on the substrate. (Though described herein as an embodiment including high-k material, other dielectrics are possible and within the scope of the disclosure.) The high-k dielectric layer 204 may be referred to herein as a portion of a dielectric layer (i.e., the combination of layer 204 and layer 402, discussed below with reference to FIG. 4, may provide a resulting single layer). In an embodiment, the high-k dielectric layer 204 is formed directly on an interfacial layer. The high-k dielectric layer 204 may be formed by atomic layer deposition (ALD) and/or other suitable methods.

In an embodiment, the high-k dielectric layer 204 is HfO₂ formed by ALD. The ALD process may include providing pulses of HfCl₄ and H₂O. A cycle of ALD (e.g., one pulse of HfCl₄ and one pulse of H₂O) may form one monolayer (or atomic layer) of HfO₂ on the substrate 204. In an embodiment, the dielectric layer 204 is formed using two cycles of an ALD process (e.g., the dielectric layer 204 is two monolayers in thickness). However, greater thicknesses of the high-k dielectric layer 204 are also possible and within the scope of the disclosure.

The method 100 then proceeds to block 106 where a first treatment is performed on the dielectric layer, described above with reference to block 104. In an embodiment, the treatment includes a radiation (e.g., UV) treatment in the presence of oxygen. For example, the treatment may include a UV radiation in the presence of O₂ and/or a UV radiation in the presence of O₃. The UV/O2 and/or UV/O3 process may be performed at room temperature. Example durations of the treatment include 30 seconds, 1 minute, 2 minutes, or greater than 2 minutes; however, numerous other durations are possible and within the scope of this disclosure.

Another example treatment that may be used in lieu of or in addition to the radiation treatment described above is a thermal anneal. In an embodiment, the thermal anneal that includes a heat treatment at less than approximately 700 C. Example durations for the thermal anneal include processes having treatments between approximately 30 and approximately 60 seconds. These process parameters are exemplary only and not intended to be limiting. Yet another example treatment that may be performed in lieu of or in addition to those described above is a chemical treatment that exposes the dielectric layer to ozone (e.g., dilute ozone). Referring to the example of FIG. 3, a treatment 302 is performed on the high-k dielectric layer 204. The treatment 302 (e.g., UV/O₂ or UV/O₃ or other treatment described above) transforms the high-k dielectric layer 204 into a treated high-k dielectric layer 204b. The treated layer 204b may differ from the dielectric layer 204 in that traps (e.g., oxygen vacancies or impurities) may be reduced.

The method 100 then proceeds to block 108 where a second portion of a dielectric layer is formed on the substrate. The second portion, together with the first portion (block 104) of the dielectric layer, may form the gate dielectric of a gate structure of a semiconductor device. In an embodiment, the dielectric layer formed in block 108 is a high-k material. The high-k material may include metal oxides, metal nitrides, metal silicates, transition metal-oxides, transition metal-nitrides, transition metal-silicates, oxynitrides of metals, metal aluminates, zirconium silicate, zirconium aluminate, combinations thereof, or other suitable compositions. Example high-k dielectrics include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), combinations thereof, and/or other suitable material. Alternatively, high-k dielectrics may optionally include other high-k dielectrics such as LaO, AlO, ZrO, TiO, Ta₂O₅, Y₂O₃, SrTiO₃ (STO), BaTiO₃ (BTO), BaZrO, HfLaO, HfSiO, LaSiO, AlSiO, (Ba,Sr)TiO₃ (BST), Al₂O₃, Si₃N₄, and/or other suitable materials.

The second portion of the dielectric layer may be formed directly on the treated first layer. The second portion of the dielectric layer may include the same composition as the first dielectric layer.

Referring to the example of FIG. 4, a high-k dielectric layer 402 is disposed on the substrate 202. The high-k dielectric layer 402 may be referred to herein as a portion of a dielectric layer (in conjunction with the dielectric layer 204, described above). In an embodiment, the high-k dielectric layer 402 is formed directly on the treated high-k dielectric layer 204b. The high-k dielectric layer 402 may be formed by atomic layer deposition (ALD) and/or other suitable processes.

In an embodiment, the high-k dielectric layer 402 is HfO₂ formed by ALD. The ALD process may include providing pulses of HfCl₄ and H₂O. A cycle of ALD (e.g., one pulse of HfCl₄ and one pulse of H₂O) may form one monolayer (or atomic layer) of HfO₂ on the substrate 202. In an embodiment, the dielectric layer 402 is formed using two cycles of an ALD process (e.g., the layer 402 is two monolayers in thickness). However, greater thicknesses of the high-k dielectric layer 402 are also possible and within the scope of this disclosure.

The method 100 then proceeds to block 110 where a second treatment is performed on the dielectric layer, described above with reference to block 108. The treatment may be substantially similar to as described with reference to block 106 of the method 100. For example, in an embodiment, the treatment includes a UV/O₂ and/or UV/O₃ process. The UV/O₂ and/or UV/O₃ process may be provided at room temperature. Example durations of the treatment include 30 seconds, 1 minute, 2 minutes, or greater than 2 minutes; however, numerous other durations are possible and within the scope of this disclosure.

Other example treatments include thermal anneals and chemical processes, such as exposure to a dilute ozone solution. In an embodiment, the thermal anneal includes exposure at less than approximately 700 C. Example durations for the thermal anneal include processes having treatments between approximately 30 and approximately 60 seconds. These process parameters are exemplary only and not intended to be limiting. The treatment described in block 110 may be the same as, or differ from, the treatment described above with reference to block 106. Referring to the example of FIG. 5, a treatment 502 is performed on the high-k dielectric layer 402. The treatment 502 (e.g., UV/O₂ or UV/O₃ or other treatment described above) transforms the high-k dielectric layer 402 into a treated high-k dielectric layer 402b. The treated layer 402b may differ from the dielectric layer 402 in that traps (e.g., oxygen vacancies or dangling bonds) may be reduced.

Though illustrated in the method 100 as providing two “cycles,” or in other words two deposition (e.g., blocks 104 and 108) and two treatments (e.g., blocks 106 and 11), the deposition of portions of a dielectric layer, and the subsequent treatment, may be repeated any number of cycles (e.g. a third portion and a third treatment may be performed) in order to reach a desired resultant thickness.

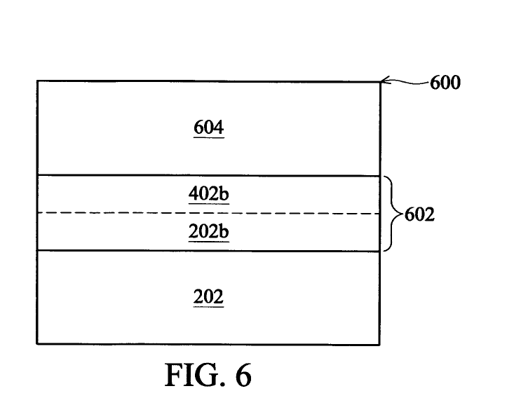

In an embodiment, the method 100 then proceeds to block 112 where a feature is formed on the dielectric layer. In an embodiment, the feature is a gate electrode and the dielectric layer provides a gate dielectric. Referring to the example of FIG. 6, a gate dielectric layer 602 is illustrated, which is the combination of layers 204b/402b. A gate electrode 604 is formed on the dielectric layer 602. A gate electrode 604 and the dielectric layer 602 may form a gate stack, or portion thereof, of the semiconductor device 600. In an embodiment, the gate electrode 604 is a metal gate. The metal gate materials may include one or more layers of material such as, liners, materials to provide appropriate work function of the gate, gate electrode materials, and/or other suitable materials. Example compositions of the metal gate 604 include Ti, TiN, TaN, Ta, TaC, TaSiN, W, WN, MoN, MoON, RuO₂, and/or other suitable materials. The metal gate 604 may include one or more layers formed by PVD, CVD, ALD, plating, and/or other suitable processes. P-type metal materials and/or n-type metal materials may be used. P-type metal materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials.

The device 600 may be an intermediate device fabricated during processing of an integrated circuit, or portion thereof, that may comprise memory cells and/or other logic circuits, passive components such as resistors, capacitors, and inductors, and active components such as P-channel field effect transistors (PFET), N-channel FET (NFET), metal-oxide semiconductor field effect transistors (MOSFET), complementary metal-oxide semiconductor (CMOS) transistors, bipolar transistors, high voltage transistors, high frequency transistors, other memory cells, and combinations thereof.

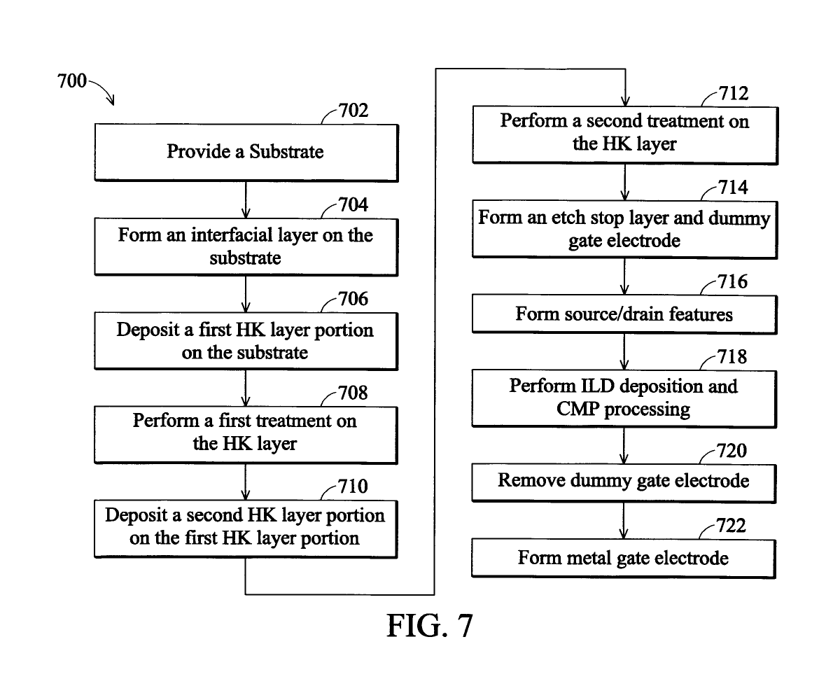

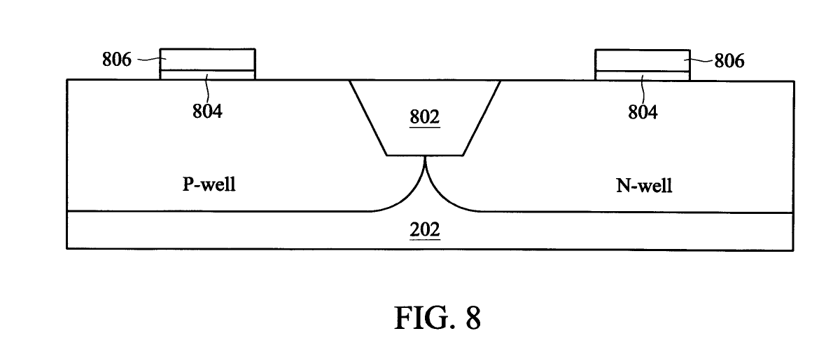

Referring now to FIG. 7, illustrated is a flow chart of a method 700. The method 700 illustrates an embodiment of a “gate last” process of forming a metal gate on a semiconductor substrate. The method 700 also illustrates an embodiment of the method 100, described above with reference to FIG. 1. FIGS. 8, 9, 10, 11, 12, and 13 illustrate cross-sectional views of an embodiment of a semiconductor device at various stages of fabrication corresponding to the method 700 of FIG. 7.

The method 700 begins at block 702 where a substrate is provided. The substrate provided may be substantially similar to the substrate 202, described above with reference to FIGS. 1 and 2. The method 700 then proceeds to block 704 where an interfacial layer is formed on the substrate. Referring to the example of FIG. 8, the substrate 202 is illustrated. The substrate 202 includes p-well and n-well regions as illustrated, however numerous other embodiments are possible. The p-well region and n-well region are separated by an isolation feature 802. An interfacial layer 804 is formed on the substrate 202. In an embodiment, the interfacial layer 804 includes a silicon oxide (SiO₂) layer (e.g., thermal or chemical oxide formation). The interfacial layer 804 may have a thickness ranging from about 3 to about 20 Angstrom (A). Alternatively, the interfacial layer 804 may optionally include HfSiO, ZrSiO, or SiON formed by ALD, CVD, PVD, thermal oxidation and nitridation, plasma oxidation and nitridation, or combinations thereof, or other suitable materials. The isolation feature 802 may be a shallow trench isolation (STI) feature formed in the substrate 202 and may isolate one or more devices from each other. The isolation feature 802 may include silicon oxide, silicon nitride, silicon oxynitride, fluoride-doped silicate glass (FSG), and/or a low k dielectric material. Other isolation methods and/or features are possible in lieu of or in addition to STI. The isolation feature 802 may be formed using processes such as reactive ion etch (RIE) of the substrate 202 to form trenches which are then filled with insulator material using deposition processes followed by a CMP process.

The method 700 proceeds to block 706 where a first portion of a high-k dielectric layer is formed on the substrate. The high-k dielectric layer may provide a gate dielectric layer of a semiconductor device. The first portion of the high-k dielectric layer may be substantially similar to the dielectric layer described above with reference to block 104 of the method 100. The high-k material may include metal oxides, metal nitrides, metal silicates, transition metal-oxides, transition metal-nitrides, transition metal-silicates, oxynitrides of metals, metal aluminates, zirconium silicate, zirconium aluminate, combinations thereof, or other suitable compositions. Example high-k dielectrics include hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), combinations thereof, and/or other suitable material. Alternatively, the high-k dielectric material may include LaO, AlO, ZrO, TiO, Ta2O5, Y2O3, SrTiO3 (STO), BaTiO3 (BTO), BaZrO, HfLaO, HfSiO, LaSiO, AlSiO, (Ba,Sr)TiO₃ (BST), Al₂O₃, Si₃N₄, and/or other suitable materials. Referring to the example of FIG. 8, a high-k dielectric layer 806 is formed on the interfacial layer 804. The high-k dielectric layer 806 may be two or more monolayers in thickness, as described above with reference to the dielectric layer 204 of FIG. 2. The high-k dielectric layer 806 provides a portion of a resulting high-k dielectric layer (e.g., gate dielectric layer).

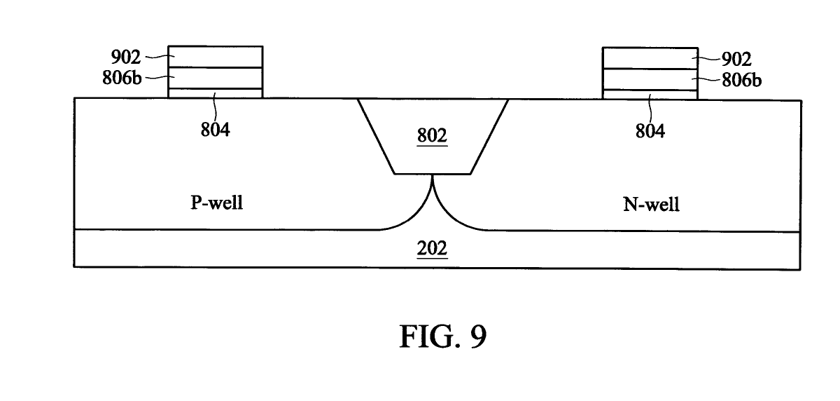

The method 700 then proceeds to block 708 where a treatment is performed on the first portion of the high-k dielectric layer. The treatment may be substantially similar to the treatment described above with reference to block 106 of the method 100. For example, in an embodiment, the treatment includes radiation (e.g., UV) while exposing the layer to O₂ and/or O₃ atmosphere. Other examples include thermal anneal processes and chemical processes including exposure to ozone (e.g., dilute ozone). Referring to the example of FIGS. 8 and 9, the treatment transforms the high-k dielectric layer 806 (FIG. 8) to a treated high-k dielectric layer 806b (FIG. 9). The treated layer 806b may differ from the layer 806 in that traps are reduced.

The method 700 then proceeds to block 710 where a second portion of a high-k dielectric layer is formed on the substrate. The second portion, along with the first portion described above in block 706, may form a gate dielectric layer of a gate structure. (It is noted that although 2 “cycles” are illustrated to form a high-k dielectric layer, the process may be repeated any number of times to produce the desired resultant thickness of dielectric.) The second portion of the high-k dielectric layer may be substantially similar to the dielectric layer of block 108 of the method 100, described above with reference to FIG. 1 and FIG. 4. Referring to the example of FIG. 9, the high-k dielectric layer 902 is formed on the high-k dielectric layer 806b.

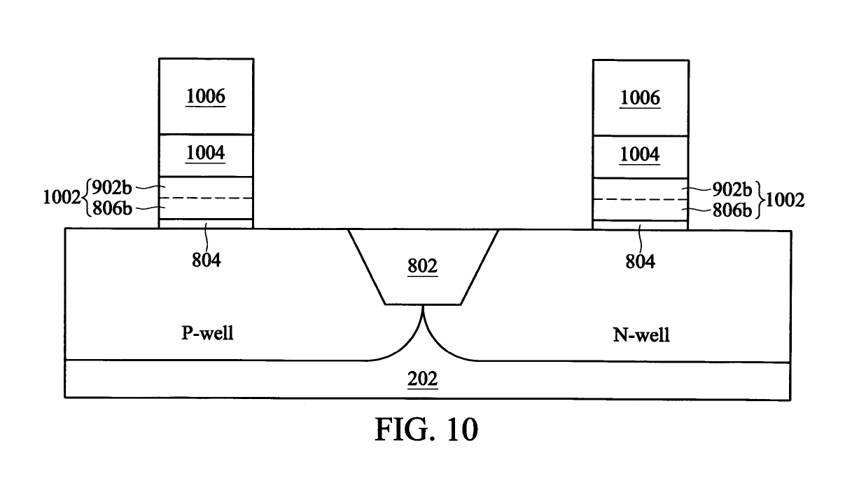

The method 700 then proceeds to block 712 where a treatment is performed on the second portion of the high-k dielectric layer. The treatment may be substantially similar to the treatment of block 110 and/or block 106 of the method 100, described above with reference to FIG. 1. For example, in an embodiment, the treatment is a UV radiation in the presence of O₂ and/or O₃ atmospheres. Referring to the example of FIGS. 9 and 10, a treatment is performed on the high-dielectric layer 902 (see FIG. 9) transforming it into treated high-k dielectric layer 902b (see FIG. 10). The treated high-k dielectric layer 902b and the treated high-k dielectric layer 806b may be of the same composition and referred to herein as portions of a high-k gate dielectric layer 1002 (see FIG. 10).

The method 700 then proceeds to block 714 where an etch stop layer and dummy gate electrode are formed on the high-k dielectric layer. Referring to the example of FIG. 10, a etch stop layer (ESL) 1004 is formed on the high-k dielectric layer 1002. A dummy gate electrode 1006 is disposed on the ESL 1004. The dummy gate electrode 1006 is a sacrificial layer. The dummy gate electrode 1006 may include polysilicon. In an embodiment, the dummy gate electrode 1006 includes amorphous silicon. In an embodiment, the ESL 1004 includes TiN.

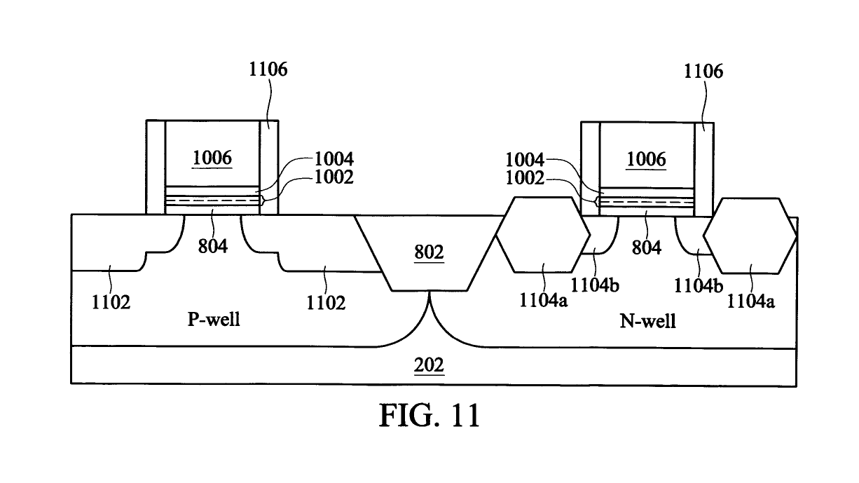

The method 700 then proceeds to block 716 where the source and drain are formed in the substrate. Referring to the example of FIG. 11, the source and drain regions 1102 are formed in the p-well and the source and drain regions 1104a and 1104b are formed in the n-well of the substrate 202. The source and drain regions 1102 may include N+ doped regions. The source and drain regions 1104a may be SiGe regions grown using processes known in the art. The source and drain regions 1104b may be source and drain extension regions including a P-doped region. The source/drain regions described are exemplary only and in alternative embodiments may include any lightly doped source/drain regions and/or heavily doped source/drain regions formed by suitable methods, selected for the desired transistor configuration. Spacers 1106 are formed adjacent the dummy gate electrode 1006. Example compositions of the spacers 1106 include silicon oxide, silicon nitride, silicon oxynitride, silicon carbide, fluoride-doped silicate glass (FSG), a low k dielectric material, combinations thereof, and/or other suitable material. The spacers 1106 may be formed by methods including deposition of suitable dielectric material and anisotropically etching the material to form the spacer 1106 profile.

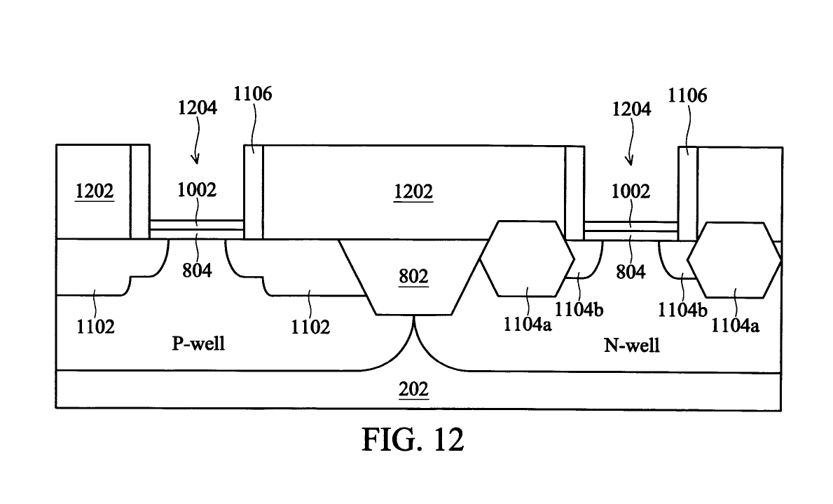

The method 700 then proceeds to block 718 where an interlayer dielectric (ILD) layer is formed and subsequently processed by a chemical mechanical polish (CMP) process. Referring the example of FIG. 12, the ILD layer 1202 is formed on the substrate 202. The ILD layer 1202 may be formed by chemical vapor deposition (CVD), high density plasma CVD, spin-on methods, sputtering, and/or other suitable methods. The ILD layer 1202 may include silicon oxide, silicon oxynitride, a low k material, and/or other suitable materials. In an embodiment, the ILD layer 1202 is a high density plasma (HDP) dielectric. The ILD layer 1202 may be planarized by a chemical mechanical polishing (CMP) process until a top portion of the dummy gate electrode 1006 is reached.

The method 700 then proceeds to block 720 where the dummy gate electrode is removed from the substrate. Referring to the example of FIG. 12, the dummy gate electrode 1006 (see FIG. 10) has been removed and trench 1204 remains. The selective removal of the dummy gate electrode 1006 provides the trench 1204 within which a metal gate may be formed. The dummy gate electrode 1006 may be removed using a wet etch and/or a dry etch. In an embodiment, a wet etch process includes exposure to a hydroxide containing solution (e.g., ammonium hydroxide), deionized water, and/or other suitable etchant solutions. The ESL 1004 provides an endpoint for the removal of the dummy gate electrode 1006. In an embodiment, the ESL 1004 is consumed during the removal of the dummy gate electrode 1006.

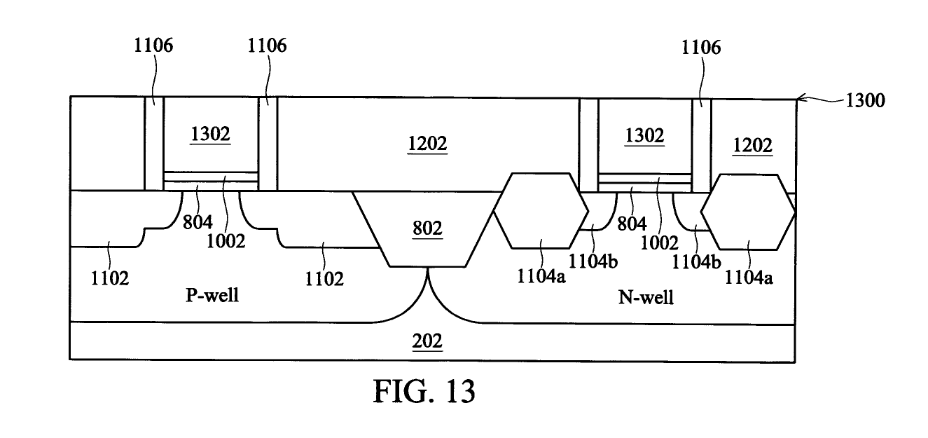

The method 700 then proceeds to block 722 where a metal gate electrode is formed in the trench. FIG. 13 illustrates a device 1300 including a metal gate 1302 formed in the trench 1202 (see FIG. 12). The metal gate 1302 may include one or more layers of material such as, liners, materials to provide appropriate work function of the gate, gate electrode materials, and/or other suitable materials. The metal deposited may be any metal material suitable for forming a metal gate or portion thereof, including work function layers, liner layers, interface layers, seed layers, adhesion layers, barrier layers, etc. The metal gate may include one or more layers including Ti, TiN, TaN, Ta, TaC, TaSiN, W, WN, MoN, MoON, RuO₂, and/or other suitable materials. The metal gate may include one or more layers formed by PVD, CVD, ALD, plating, and/or other suitable processes. P-type metal materials and/or n-type metal material may be used. P-type metal materials include compositions such as ruthenium, palladium, platinum, cobalt, nickel, and conductive metal oxides, and/or other suitable materials. N-type metal materials include compositions such as hafnium, zirconium, titanium, tantalum, aluminum, metal carbides (e.g., hafnium carbide, zirconium carbide, titanium carbide, aluminum carbide), aluminides, and/or other suitable materials. A fill metal may also be deposited to substantially or completely fill the remainder of the trench. The fill metal may include titanium nitride, tungsten, titanium, aluminum, tantalum, tantalum nitride, cobalt, copper, nickel, and/or other suitable materials. The fill metal may be deposited using CVD, PVD, plating, and/or other suitable processes.

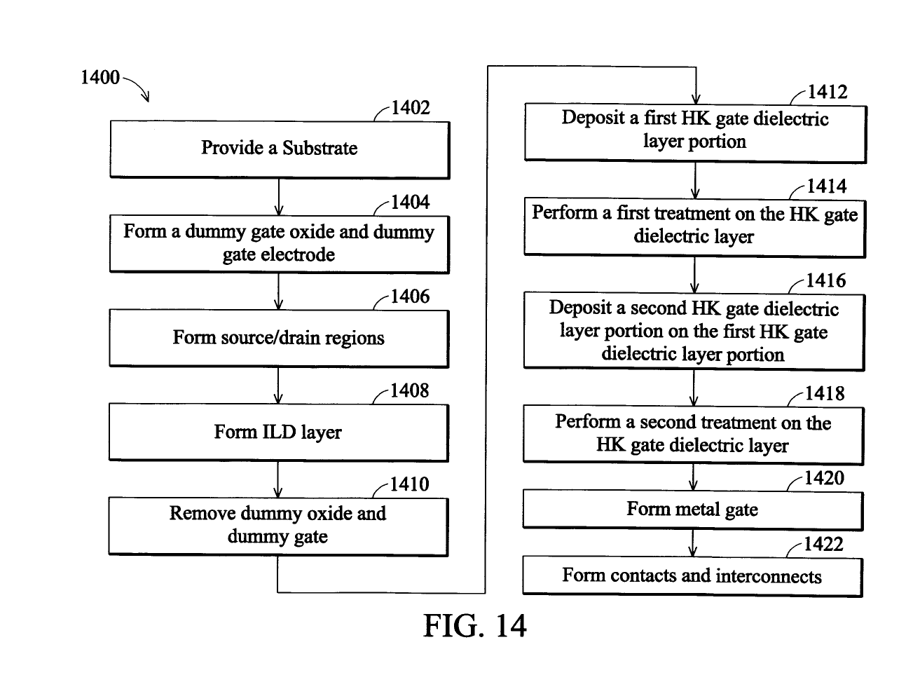

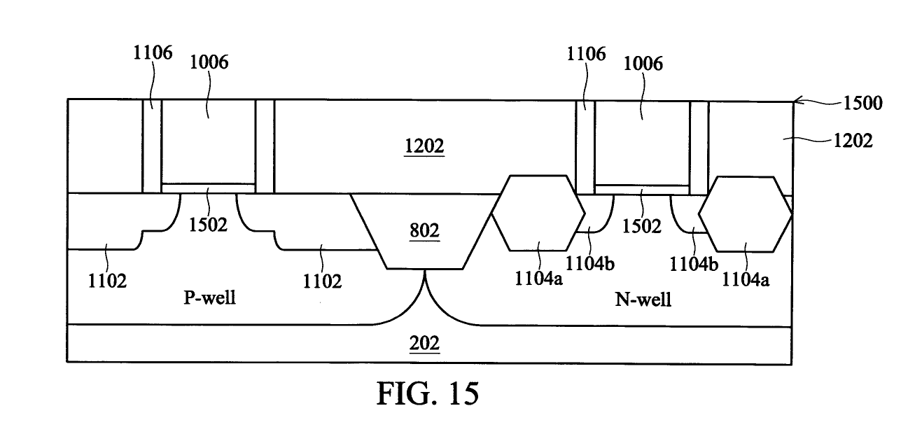

Referring now to FIG. 14, illustrated is a flow chart of a method 1400 of forming a semiconductor device having metal gate using a “gate last” process that also includes providing the gate dielectric “last” (e.g., after the removal of the sacrificial gate electrode). The method 1400 may provide an embodiment of the method 100, described above with reference to FIG. 1. FIGS. 15, 16, 17, 18, and 19 illustrate cross-sectional views of an embodiment of a semiconductor device at various stages of fabrication corresponding to the method 1400 of FIG. 14.

The method 1400 begins at block 1402 where a substrate is provided. The substrate may be substantially similar to the substrate of block 102 of the method 100, described above with reference to FIGS. 1 and 4. The method 1400 then proceeds to block 1404 where a dummy gate dielectric (e.g., oxide) and dummy gate electrode (e.g., a dummy gate stack) are formed on the substrate. The dummy gate oxide and dummy gate electrodes may be sacrificial layers. The method 1400 then proceeds to block 1406 where source and drain regions are formed adjacent the dummy gate stack. Spacer elements may be formed and used as masking elements in forming the source and drain regions. The method 1400 then proceeds to block 1408 where an ILD layer is formed. Following the formation of the ILD layer, a CMP process may be performed to planarize the layer and expose the top of the dummy gate stack. The foregoing blocks of FIG. 14 are illustrated in an exemplary embodiment of FIG. 15. In FIG. 15, a device 1500 is illustrated having a substrate 202 including a p-well and an n-well; an isolation feature 802; source and drain regions 1102, 1104a, 1104b; an ILD layer 1202; spacers 1106; a dummy gate electrode 1006; and an underlying dummy gate dielectric 1502. The device 1500 may further include an interfacial layer. One or more of these layers may be substantially similar to those described above with reference to FIGS. 7-13. The ILD layer 1202 has been planarized such that the top of the gate stack, including dummy gate electrode 1006, is exposed.

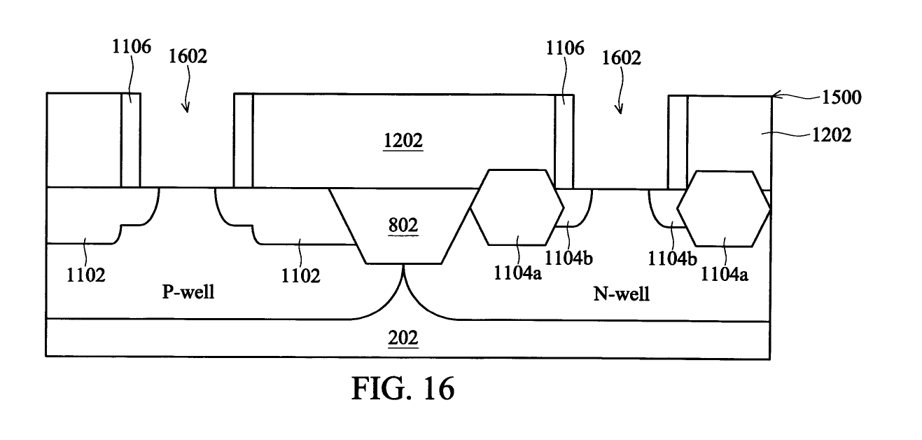

The method 1400 then proceeds to block 1410 where the dummy gate electrode and dummy gate dielectric are removed. The dummy gate electrode removal may be substantially similar to block 720 of the method 700, described above with reference to FIG. 7. Referring to the example of FIG. 16, the dummy gate stack has been removed to form a trench 1602. In an embodiment, the trench 1602 exposes a surface of the substrate 202.

The method 1400 then proceeds to block 1412 where a first portion of a high-k gate dielectric layer is formed on the substrate. The high-k gate dielectric layer may be substantially similar to the dielectric layer of block 104 of the method 100, described above with reference to FIG. 1, and/or the high-k dielectric layer of block 706 of the method 700, described above with reference to FIG. 7. For example, the portion of the dielectric layer may be a portion of a layer which provides a gate dielectric layer. The method 1400 then proceeds to block 1414 where a treatment is performed on the first portion of the high-k gate dielectric layer. The treatment may be substantially similar the treatment of block 106 of the method 100, described above with reference to FIGS. 1 and 3. For example, in an embodiment, the treatment may be a UV radiation treatment in the presence of O₂ and/or O₃. Other example treatments include a thermal anneal and a chemical treatment including ozone.

The method 1400 then proceeds to block 1416 where a second portion of the high-k gate dielectric layer is formed on the first portion of the high-k gate dielectric layer. The second high-k gate dielectric layer may be substantially similar to the dielectric layer of block 108 of the method 100 and/or the high k dielectric layer of block 710 of the method 700, described above with reference to FIGS. 1 and 7, respectively. The method 1400 then proceeds to block 1418 where a second treatment is performed on the high-k gate dielectric layer (e.g., the second portion). The treatment may be substantially similar to the treatments described above with reference to FIGS. 1 and 7. For example, in an embodiment the treatment may be a UV radiation treatment in the presence of O₂ and/or O₃. Other example treatments include a thermal anneal and a chemical treatment including ozone.

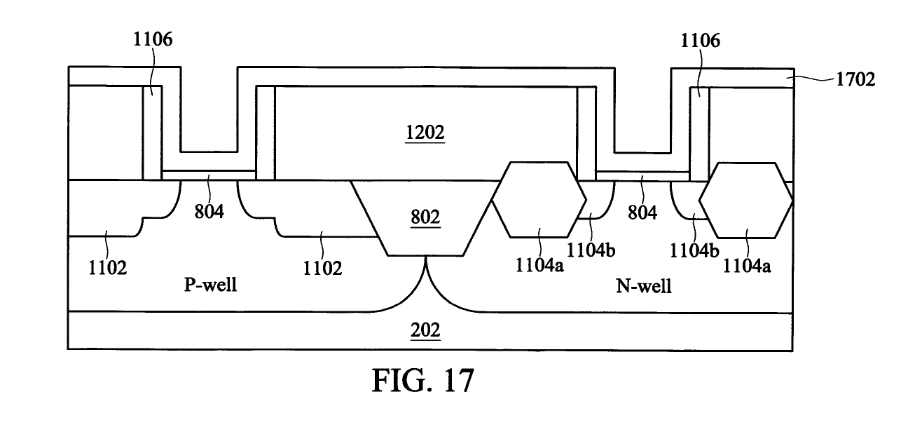

Referring to the example of FIG. 17, a high-k gate dielectric layer 1702 is formed on the substrate 202. An interfacial layer 804 is also formed on the substrate 202 underlying the high-k gate dielectric layer 1702. The high-k gate dielectric layer 1702 includes a first portion and a second portion, as described above. Both portions are independently treated after their formation (e.g., deposition). The high-k gate dielectric layer 1702 may be formed using any plurality of “portions,” each “portion” provided by a process including forming a layer of dielectric material (e.g., two or more monolayers) and treating the layer.

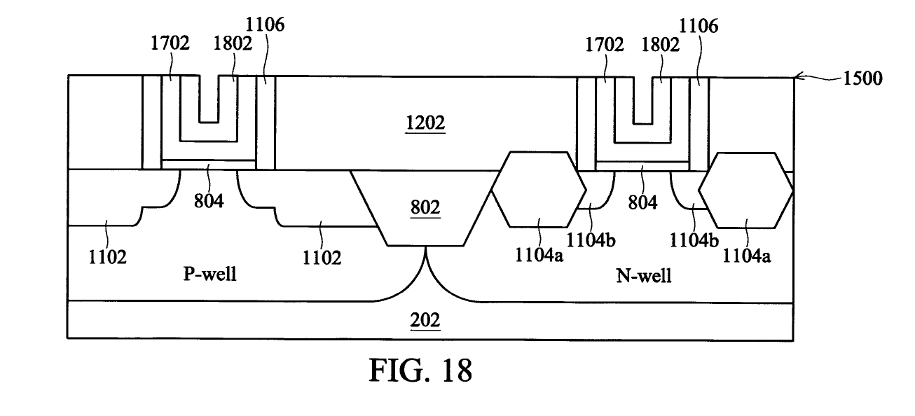

The method 1400 then proceeds to block 1420 where a metal gate is formed on the substrate. Referring to the example of FIG. 18, a metal gate 1802 is formed on the substrate 202 overlying the dielectric layer 1702. The metal gate 1802 may be substantially similar to the metal gate 1302, described above with reference to FIGS. 7 and 13. A chemical mechanical polishing process may be used to planarize the device 1500.

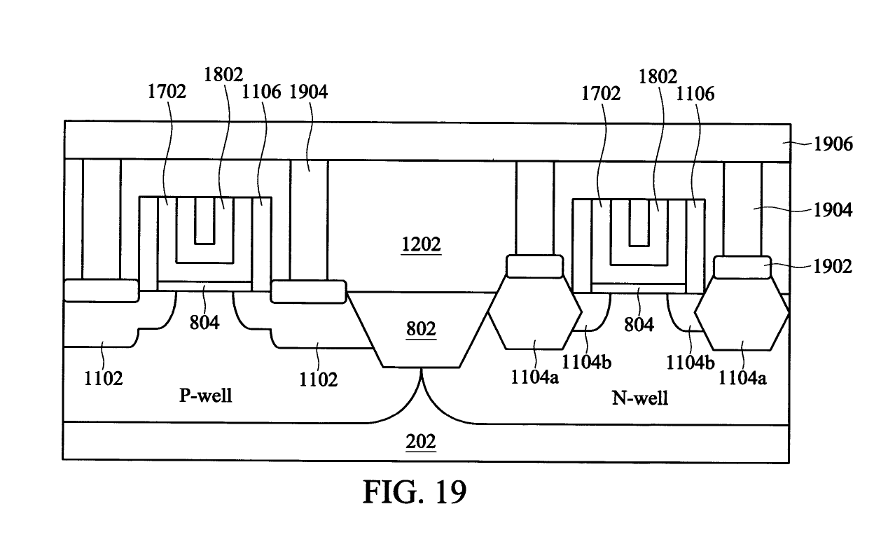

The method 1400 then proceeds to block 1422 where contacts and interconnect features are formed on the substrate. Referring to the example of FIG. 19, contact features 1902 and interconnect features including vias 1904 and conductive lines 1906 are formed on the substrate 202. The contact features 1902 coupled to the source/drain regions 1102, 1104b may include silicide such as nickel silicide, cobalt silicide, tungsten silicide, tantalum silicide, titanium silicide, platinum silicide, erbium silicide, palladium silicide, or combinations thereof. The contact features 1902 may be formed on the source/drain regions 1102, 1104b by a salicide (self-aligned silicide) process. The vias and conductive lines 1906 include various conductive materials such as copper, tungsten, aluminum, silicide, combinations thereof, and/or other suitable materials. In one example, a damascene process is used to form copper multilayer interconnection structure.

Thus, one or more methods are described for forming a gate dielectric layer (e.g., a high-k gate dielectric layer). One or more of the embodiments provides for multiple deposition and multiple treatment steps in forming the layer. Benefits of one or more of the embodiments illustrated include enhancing the equivalent oxide thickness (EOT) of the semiconductor device. This may be done by decreasing the thermal budget required to form the gate dielectric layer and therefore, the semiconductor device in general. Other benefits include recovering pre-existing traps in the gate dielectric layer which may improve the layer quality. In one or embodiments, a suppression of an increase in gate leakage current (Jg) and inhibition interface layer re-growth may be realized. These are typical disadvantages of the prior art processes that include high temperature post-deposition anneals of a gate dielectric layer.

Accordingly, the present disclosure provides a method of forming a dielectric layer such as a high-k gate dielectric layer. While the formation has been disclosed as directed to a metal gate last process, a high-k gate dielectric last process, and/or other embodiments, the present disclosure may benefit any semiconductor process now known or developed in the future including, for example, a gate first metal gate process. While the preceding description shows and describes one or more embodiments, it will be understood by those skilled in the art that various changes in form and detail may be made therein without departing from the spirit and scope of the present disclosure. Therefore, the claims should be interpreted in a broad manner, consistent with the present disclosure.

What is claimed is:

1. A method of fabricating a semiconductor device, comprising:
providing a semiconductor substrate;
forming a first high-k dielectric layer on the semiconductor substrate;
performing a first treatment on the first high-k dielectric layer, thereby forming a first treated high-k dielectric layer;
forming a second high-k dielectric layer on the first treated high-k dielectric layer; and
performing a second treatment on the second high-k dielectric layer.

2. The method of claim 1, wherein the first treatment is at least one of a UV radiation in an O₂ environment and a UV radiation in an O₃ environment.

3. The method of claim 2, wherein the second treatment is at least one of a UV radiation in an O₂ environment and a UV radiation in an O₃ environment.

4. The method of claim 2, wherein the first treatment is greater than approximately 30 seconds.

5. The method of claim 1, wherein the first and second high-k dielectric layer have the same composition.

6. The method of claim 1, further comprising:
forming a metal gate overlying the second high-k dielectric layer.

7. The method of claim 1, further comprising:
forming a dummy gate structure on the semiconductor substrate.

8. The method of claim 1, wherein at least one of the first treatment and the second treatment includes a thermal anneal.

9. The method of claim 1, further comprising:
forming an interfacial layer on the substrate underlying the first high-k dielectric layer.

10. The method of claim 1, wherein the first treatment includes treating the surface of the first high-k dielectric layer with dilute ozone.

11. A method, comprising:
forming a first portion of a gate dielectric layer on a semiconductor substrate;
performing a first treatment on the first portion of the gate dielectric layer;
forming a second portion of the gate dielectric layer directly on the treated first portion;
performing a second treatment on the second portion of the gate dielectric layer, and
forming a gate electrode on the gate dielectric layer.

12. The method of claim 11, wherein the forming the first portion of the gate dielectric layer includes performing at least two cycles of an atomic layer deposition (ALD) process.

13. The method of claim 11, wherein the forming the second portion of the gate dielectric layer includes performing at least two cycles of an atomic layer deposition (ALD) process.

14. The method of claim 11, further comprising:
depositing a third portion of the gate dielectric layer on the treated second portion; and
performing a third treatment on the third portion of the gate dielectric layer.

15. The method of claim 11, wherein the gate dielectric layer is selected from the group consisting of hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), and combinations thereof.

16. A method of semiconductor fabrication, comprising:
forming a dummy gate structure on a semiconductor substrate;
forming a source and drain region adjacent the dummy gate structure;
thereafter, removing the dummy gate structure to form a trench;
depositing a first portion of a high-k dielectric layer on the semiconductor substrate including in the trench;
treating the first portion of the high-k dielectric layer;
depositing a second portion of the high-k dielectric layer on the substrate overlying the treated first portion of the high-k dielectric layer;
treating the second portion of the high-k dielectric layer; and
forming a metal gate on the treated second portion of the high-k dielectric layer.

17. The method of claim 16, wherein the treating the first portion includes a first treatment and the treating the second portion includes a second treatment, and wherein the first and second treatments are selected from the group consisting of a chemical treatment, a thermal anneal treatment, and a radiation treatment.

18. The method of claim 16, wherein the depositing the first portion of the high-k dielectric layer deposits less than ten atomic layers of the high-dielectric layer.

19. The method of claim 16, further comprising:
forming an interfacial layer on the semiconductor substrate in the trench prior to forming the first portion of the high-k dielectric layer.

20. The method of claim 16, wherein the high-k dielectric layer is hafnium oxide (HfO₂).
